(19) United States
(12) Patent Application Publication
(10) Pub. No.: US 2025/0174588 A1
(43) Pub. Date: May 29, 2025

(54) METHOD OF MANUFACTURING ELECTRONIC COMPONENTS WITH WETTABLE FLANKS

(71) Applicant: STMicroelectronics International N.V., Geneva (CH)

(72) Inventor: Ludovic FALLOURD, Louans (FR)

(73) Assignee: STMicroelectronics International N.V., Geneva (CH)

(21) Appl. No.: 18/951,283

(22) Filed: Nov. 18, 2024

(30) Foreign Application Priority Data
Nov. 23, 2023 (FR) 2312922

(51) Int. Cl. H01L 23/00; H01L 23/31

(52) U.S. Cl. CPC H01L 24/13; H01L 23/3107; H01L 24/11; H01L 2224/1111; H01L 2224/1112; H01L 2224/13082; H01L 2224/13111

(57) ABSTRACT

Process for manufacturing electronic components with wettable flanks from a substrate covered by connection terminals and in which chips are formed, the process comprising the following steps: a) solder connection pads to the connection terminals, b) coat the connection pads with a layer of insulating resin, c) thin the insulating resin layer until it reaches the core of the connection pads, d) form cavities by removing part of the connection pads and part of the insulating resin layer, so as to make part of the flanks of the components accessible, e) deposit a layer of conductive material on the flanks of the components and on the connection pads, f) separate the chips.

### CROSS-REFERENCE TO RELATED APPLICATION(S)

This application claims the priority benefit of French patent application number 2312922, filed on Nov. 23, 2023, entitled “Procédé de fabrication de composants électroniques,” which is hereby incorporated by reference to the maximum extent allowable by law.

### BACKGROUND

### Technical Field

The present description relates to the manufacture of electronic components. More specifically, it applies to the manufacture of so-called surface-mount components, i.e., components having, on at least one side, one or more connection metallizations designed to be soldered to corresponding connection pads on an external device, such as a printed circuit board or another component.

### Description of the Related Art

In some applications, there is a use for surface-mounted components in which connection metallizations designed to be soldered to an external device extend to the component flanks. These are known as “wettable flank” components. When the component is mounted in its environment (e.g., on a printed circuit board), the connection metallizations (also known as electrical contacts) are soldered or brazed to corresponding metal tracks or elements on the PCB side. Some of the soldering material then rises to the sides of the components, enabling visual inspection of connection quality.

This use exists, for example, in the automotive or medical fields, and more generally in all areas where the reliability of electrical connections must be guaranteed once the circuits have been installed in their environment.

### BRIEF SUMMARY

There is a use for improving at least some aspects of known processes for manufacturing electronic components with wettable flanks.

This is achieved by a process for manufacturing electronic components with wettable flanks from a substrate covered by connection terminals and in which chips are formed, the process comprising the following steps:
a) solder connection pads to the connection terminals of the chips,
b) coat the connection pads with an insulating resin layer,
c) thin the insulating resin layer until it reaches the core of the connection pads,
d) form cavities by removing part of the connection pads and part of the insulating resin layer, so as to make part of the flanks of the components accessible,
e) deposit a layer of conductive material on the flanks of the components and on the core of the connection pads,
f) separate the chips through cavities.

According to an embodiment, the connection pads comprise an electrically conductive core, covered by a layer of solderable material.

According to an embodiment, the solderable material is Sn or a tin alloy, such as SnAg, or SnAgCu.

Advantageously, the electrically conductive core is made of copper.

According to an embodiment, the conductive material and the solderable material are identical.

According to an embodiment, step e) is carried out by screen-printing.

This is achieved by an electronic component with wettable flanks comprising a chip having connection terminals protected by a housing comprising a first main face, flanks and a second main face, a layer of conductive material covering part of the flanks and extending over the first main face, the layer of conductive material being electrically connected to the connection terminals of the chip by means of connection pads soldered to the connection terminals.

According to an embodiment, the connection pads comprise an electrically conductive core, at least partially covered by a layer of material soldered to the connection terminals.

According to an embodiment, the layer of conductive material is a layer of Sn or an alloy of tin, such as SnAg or SnAgCu.

According to an embodiment, an insulating resin layer covers the first main face of the chip between the connection pads.

### BRIEF DESCRIPTION OF THE SEVERAL VIEWS OF THE DRAWINGS

The foregoing features and advantages, as well as others, will be described in detail in the following description of specific embodiments given by way of illustration and not limitation with reference to the accompanying drawings, in which:

FIG. 1 shows a schematic cross-section of an electronic component with wettable flanks according to a particular embodiment;

FIG. 2A, FIG. 2B, FIG. 2C, FIG. 2D, FIG. 2E and FIG. 2F are cross-sectional views illustrating steps in a process for manufacturing an electronic component with wettable flanks according to a particular embodiment;

FIG. 3 shows a top view of an electronic component with wettable flanks obtained by the process described in FIGS. 2A to 2F;

FIG. 4A and FIG. 4B are cross-sectional views illustrating steps in a process for manufacturing an electronic component with wettable flanks according to another particular embodiment;

FIG. 5 shows a top view of an electronic component with wettable flanks obtained by the process described in FIGS. 4A and 4B;

FIG. 6 is a Scanning Electron Microscope (SEM) image of a spherical core-shell connection pad in a particular embodiment.

### DETAILED DESCRIPTION

Like features have been designated by like references in the various figures. In particular, the structural and/or functional features that are common among the various embodiments may have the same references and may dispose identical structural, dimensional and material properties.

For the sake of clarity, only the operations and elements that are useful for an understanding of the embodiments described herein have been illustrated and described in detail.

Unless indicated otherwise, when reference is made to two elements connected together, this signifies a direct connection without any intermediate elements other than conductors, and when reference is made to two elements coupled together, this signifies that these two elements can be connected or they can be coupled via one or more other elements.

In the following disclosure, unless indicated otherwise, when reference is made to absolute positional qualifiers, such as the terms “front,” “back,” “top,” “bottom,” “left,” “right,” etc., or to relative positional qualifiers, such as the terms “above,” “below,” “higher,” “lower,” etc., or to qualifiers of orientation, such as “horizontal,” “vertical,” etc., reference is made to the orientation shown in the figures.

Unless specified otherwise, the expressions “around,” “approximately,” “substantially” and “in the order of” signify within 10%, and preferably within 5%.

Electronic components are used in a wide range of industrial sectors, particularly in the automotive and medical fields.

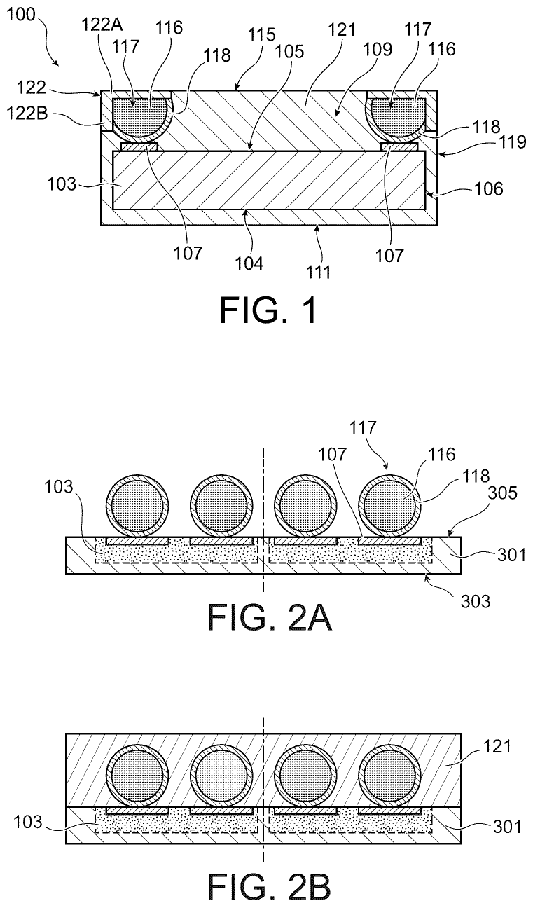

FIG. 1 shows a schematic cross-section of an electronic component 100.

The electronic component 100 consists of an electronic chip 103 and a housing 109. In one example, the chip 103 is formed from a semiconductor substrate, such as silicon. It may also be SiC. Alternatively, the substrate can be glass or sapphire.

The chip comprises a front side 105 (also known as the first side or front face), a rear side 104 (also known as the second side or rear face) and sidewalls 106 (also known as side faces). The lower side 104 is opposite the upper side 105.

One or more connection terminals 107 (also known as electrical contacts) are formed on the top surface 105 of the microchip 103, enabling it to be connected to other elements (microchips or electronic devices).

The electrical connection terminals 107 are also called “UBM” (Under Bump Metallization). The electrical connection terminals 107 are made of a conductive material specifically designed to receive the connection pads 117, and in particular to adhere well to the pads 117. The electrical connection terminals 107 comprise at least one of the following elements: gold, titanium, nickel, copper, silver, tin or tungsten. Preferably, they comprise gold or copper. Connection terminals 107 can be plated.

The electrical connection terminals 107 are, for example, 10 to 50 μm, or even 10 to 30 μm from the chip side wall. The distance will depend on the size of the connection pads 117. The electrical connection terminals 107 can be positioned on the top surface 105 of the chip 103 or flush with the top surface (i.e., be at the same level as the top surface 105 of the chip 103).

The chip 103 may comprise one or more discrete components. The discrete component(s) are, for example, selected from transistors, diodes, thyristors, triacs, filters, etc. The chip 103 may comprise one or more electronic circuits. The chip 103 can be used to implement various electronic functions.

Component 100 is an integrated component.

The chip 103 is protected by the housing 109. More specifically, the casing 109 covers at least the front side 105. Preferably, as shown in FIG. 1, it may also cover the sides 106 of the chip 103 and/or the rear side 104 of the chip 103.

Housing 109 is made of an electrically insulating material.

In order to connect the component 100 to other electronic components and/or circuits, the housing 109 also includes connection pads 117 (also known as housing contacts or contact covers). The connection pads 117 are positioned on the top surface 105 of the chip 103. Each pad 117 is connected to an electrical terminal 107 on the chip 103.

Connection pads 117 can be metallic elements.

Connection pads 117 are, for example, metal balls. They may be made of copper, nickel or any other non-fusible material.

Connection pads 117 can be elements comprising an electrically conductive core 116 covered by a layer 118 (also called a shell) of solderable material.

Preferably, the electrically conductive core 116 is made of copper.

Preferably, the solderable material is tin or one of its alloys, such as SnAgCu or SnAg. Layer 118 acts as an oxidation barrier layer.

Electrical connection terminals 107 on chip 103 and connection pads 117 are positioned in apertures in an insulating resin layer 121 covering chip 103.

Component 100 is a component with a wettable flank, i.e., at least part of its sidewall is covered by a layer 122 of a wettable and/or solderable material, i.e., a material that can be soldered or otherwise mechanically attached (e.g., conductive adhesive, sintering).

The layer 122 of wettable material covers part of the flanks 119 of the component 100 and extends over a first main face 115 of the component 100, forming a continuous layer with a first part 122A covering part of the first main face 115 of the component 100 and a second part 122B covering part of the flanks 119 of the component 100.

The wettable material is in direct contact with the connection pads 117. There is no element between the connection pads 117 and the wettable material. It is in direct contact on the flanks 119 and on the first main face 115.

The wettable material is preferably a brazeable material, such as Sn, SnAg or SnAgCu or another material with a higher melting point.

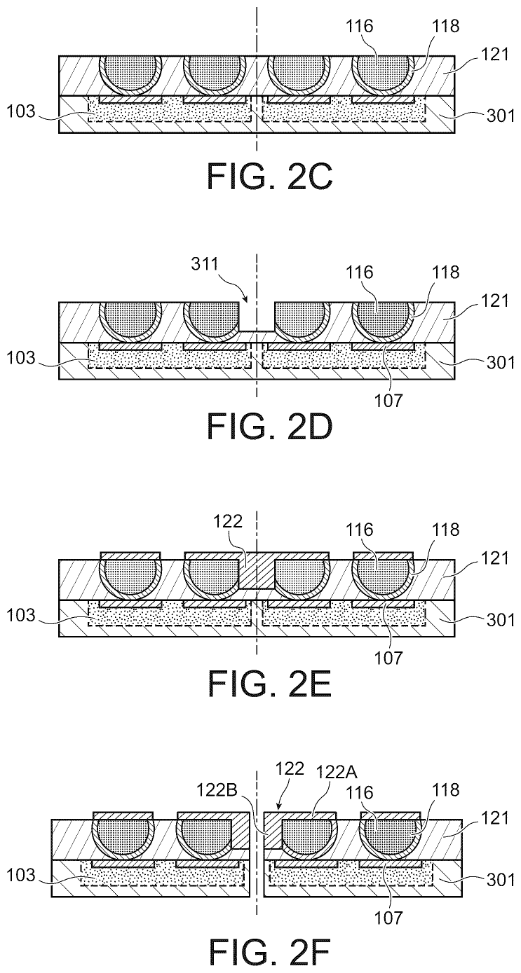

We will now describe in more detail the manufacturing process for such a component 100 with reference to FIGS. 2A to 2F.

The process is based on a substrate 301 covered by connection terminals 107 and in which chips 103 are formed.

The process comprises the following steps:
a) soldering connection pads 117 to connection terminals 107, the connection pads 117 preferably comprising an electrically conductive core 116, covered by a coating layer 118 of a solderable material (FIG. 2A),
b) depositing a layer of insulating resin 121 on the substrate 301, the layer of insulating resin 121 encapsulating the connection pads 117 and the connection terminals 107 (FIG. 2B),
c) thinning the insulating resin layer 121 until it reaches the connection pads 117 and if applicable the core 116 of the connection pads 117 (FIG. 2C),
d) forming cavities 311 between the chips 103 by locally removing part of the connection pads 117 and part of the insulating resin layer 121, so as to make part of the flanks 119 of the components 100 accessible (FIG. 2D),
e) applying a layer of conductive material 122 on the flanks of the components 100 and on the connection pads 117 (FIG. 2E),
f) separating the chips 103 by cutting into the cavities 311 (FIG. 2F), thereby obtaining components 100 with wettable flanks.

In step a), manufacture of the discrete component(s) and/or integrated circuit(s) forming the 100 components is complete. The components 100 are formed from a single substrate 301, and have not yet been individualized. On the figures, the chips 103 are delimited by a dashed line in the substrate 301. The substrate 301 has a first face 305 (upper or front face) and a second face 303 (back or rear face). Adjacent chips 103 are spaced from each other by a portion of the substrate 301. Said differently, the portion of the substrate 301 separates adjacent chips 103.

Substrate 301 is, for example, a semiconductor substrate, such as silicon or SiC.

Substrate 301 has a thickness of between 300 and 900 μm, for example, a thickness of around 725 μm.

In addition, electrical connection terminals 107, described in relation to FIG. 1, have been formed on an upper face 305 of the substrate 301 (FIG. 2A).

In step a), the connection pads 117 are soldered to the connection terminals 107.

As shown in FIGS. 2A to 2F and 3, connection pads 117 can be balls (i.e., spherical in shape). It is obvious that the drawings are schematic representations and that in reality the soldering connection pads 117 and connection terminals 107 have a larger contact surface than a single point of contact as they are soldered to each other.

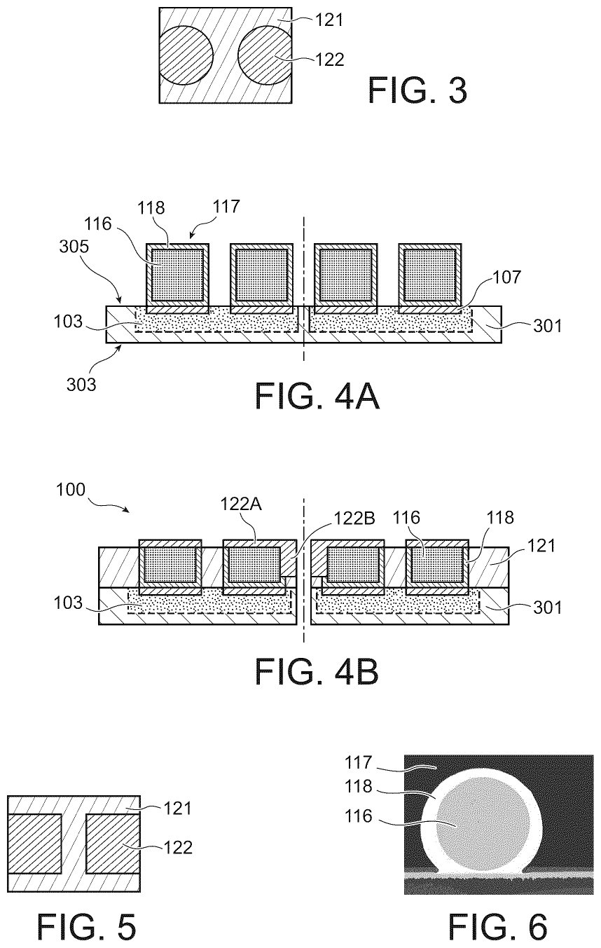

Alternatively, as shown in FIGS. 4A, 4B and 5, the connection studs can be columns. These may be pillars with a square, circular or rectangular cross-section.

Preferably, the connection pads 117 comprise a core 116 made of a first material and a shell (or coating) 118 made of a second material.

The shell 118 preferably covers the core continuously. The shell is, for example, between 10 and 20 μm thick.

The electrically conductive core 116 is preferably made of copper.

The shell 118 or coating is made of a material that can be soldered to the terminal pads. In particular, it is tin or a tin alloy, such as SnAg or SnAgCu.

FIG. 6 shows, by way of illustration and not as a limitation, an SEM image of a spherical connection pad 117 with a copper core and a tin-based alloy shell.

In a variant not shown, the connection pads are metal balls. The balls are not covered by a shell. They may be copper or nickel balls.

In step b), a layer of insulating resin 121 is deposited on the substrate 301.

More specifically, the insulating resin layer 121 is deposited on the first face 305 of the substrate 301 and on the pads 117. In this way, the pads 117 are arranged within the resin. The insulating resin layer 121 forms a first part of the component housing 100. By way of example, layer 121 can be deposited by screen printing, compression or injection molding. This first part of the casing therefore protects the upper face of the 100 components.

The resin is an electrically insulating resin. More particularly, the resin comprises at least one base material to which electrically insulating particles are added. The base material is selected from the group comprising: epoxy-type resins, phenolic-type resins, acrylic-type resins. Preferably, the resin is an epoxy-type resin. The particles are, for example, oxide particles, in particular alumina or silica particles.

Polymerization is carried out, for example, under ultraviolet (UV) radiation or by thermal activation. Annealing can be carried out prior to step c).

In step c), a thinning step is carried out from the front face to remove the part of the insulating resin 121 covering the connection pads 117 and the upper part of the connection pads 117 until the core 116 of the connection pads 117 is reached.

The thinning step on the front face can be carried out by grinding. Mechanical polishing is the preferred.

In step d), cavities 311 are formed between the chips 103 in order to remove part of the resin layer 121 and part of the connection pads 117. The core 116 of the connection pads 117 is thus also accessible from the side.

The resulting cavities 311 extend from the front face and to a depth corresponding at least to the height of the layer of conductive material 122 covering the sidewalls of the components 100 described below. The height of the cavity 311 is less than the thickness of the insulating resin layer 121 in order to insulate the wettable flanks from the substrate 301.

Step d) is carried out using a cutting device. The cutting device is, for example, a mechanical engraving tool such as a saw, or a laser engraving tool. In a preferred embodiment, the cutting device is a laser. In addition, when the cutting device is a laser, the cutting technique used can be a Laser Direct Structuring (LDS) technique.

In step e), a layer 122 of conductive material is deposited so as to cover at least part of the sides 119 of the components 100 and the connection pads 117.

The layer 122 of conductive material can be deposited by a printing method, an additive deposition method or by immersion in a bath. It is, for example, possible to deposit an antioxidant material on metal surfaces. The deposition is selective.

The layer 122 of conductive material is advantageously deposited locally by a dispensing technique, preferably by screen printing, in particular through a mask.

Alternatively, it can be a full-plate deposition.

At the end of step e), the cavities 311 are filled with conductive material and the core 116 of the connection pads 117 is covered by the layer 122 of conductive material. The core 116 is thus completely covered by a protective layer formed partly by the shell 118 and partly by the layer 122. The core is thus protected from the external environment, and in particular from oxidation, which is particularly advantageous in the case of a copper core 116.

In step f), the components 100 are separated by cutting through the cavities 311. The 100 components are thus separated from each other. In some embodiments, cutting includes cutting through the portion of the substrate 301 that separates adjacent chips 103.

Alternatively, the steps can be performed in the following order: a), b), c), d), f) and e). Once the cavities 311 have been formed, it is possible to continue with a complete cut (step f)) and then to deposit the layer of conductive material 122 (step e)). Advantageously, the deposited layer is an organic layer. It also serves as a protective layer against oxidation.

The process can also include a back-side thinning step. To do this, the structure is turned over and attached by its front side, i.e., face 305, to a support. The support is, for example, a strip of adhesive tape. The structure is then thinned on its back side 303 so that the substrate 301 has its final thickness.

The process can advantageously include a step during which an additional insulating layer is deposited on the rear face 303 of the structure to form the rear face of the housing 111 and/or on the side faces 106 of the chip 103.

The additional insulating layer is made of an electrically insulating material, e.g., a resin of the same type as the resin in layer 121. In another example, the materials of the layers are different.

At the end of the process, the components 100 obtained are surface-mounting devices (SMDs) of the “flip-chip” type, i.e., they can be attached to an external device, such as a printed circuit board or another component, by their front face, i.e., the face on which the pads 117 of the housing 109 are arranged.

To achieve this, a brazing material is positioned between the component 100 and the external device. During soldering, the soldering material rises up to the sides 119 of the 100 components, allowing verification that soldering has been carried out correctly.

Such components 100 are particularly interesting for guaranteeing the reliability of electrical connections, once the circuits have been mounted in their environment.

Various embodiments and variants have been described. Those skilled in the art will understand that certain features of these embodiments can be combined and other variants will readily occur to those skilled in the art.

Finally, the practical implementation of the embodiments and variants described herein is within the capabilities of those skilled in the art based on the functional description provided hereinabove.

A process for manufacturing electronic components (100) with wettable flanks from a substrate (301) covered by connection terminals (107) and in which chips (103) are formed, the process is summarized as including the following steps: a) solder connection pads (117) to the connection terminals (107) of the chips (103), b) coat the connection pads (117) with an insulating resin layer (121), c) thin the insulating resin layer (121) until it reaches the core (116) of the connection pads (117), d) form cavities (311) by removing part of the connection pads (117) and part of the insulating resin layer (121), so as to make part of the flanks (119) of the components (100) accessible, e) deposit a layer of conductive material (122) on the flanks (119) of the components (100) and on the core of the connection pads (117), f) separate the chips (103) through cavities (311).

The connection pads (117) include an electrically conductive core (116), covered by a layer of solderable material (118).

The solderable material is Sn or a tin alloy, such as SnAg, or SnAgCu.

The electrically conductive core (116) is made of copper.

The conductive material and the solderable material are identical.

Step e) is carried out by screen-printing.

Electronic component (100) with wettable flanks is summarized as including a chip (103) having connection terminals (107), the chip (103) being protected by a housing (109) including a first main face (115), flanks (119) and a second main face, a layer of conductive material (122) covering part of the flanks (119) and extending over the first main face (115), the layer of conductive material (122) being electrically connected to the connection terminals (107) of the chip (103) by means of connection pads (117) soldered to the connection terminals (107).

The connection pads (117) include an electrically conductive core (116), at least partially covered by a layer of material (118) soldered to the connection terminals (107).

The layer of conductive material (122) is a layer of Sn or an alloy of tin, such as SnAg or SnAgCu.

An insulating resin layer (121) covers the first main face (105) of the chip (103) between the connection pads (117).

The various embodiments described above can be combined to provide further embodiments. Aspects of the embodiments can be modified, if necessary to employ concepts of the various patents, applications and publications to provide yet further embodiments.

These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. A method for manufacturing an electronic component, comprising:
forming, on each of a plurality of connection terminals on a plurality of chips, a connection pad;
coating each connection pad with an insulating resin layer;
thinning the insulating resin layer until it reaches a core of each connection pad;
forming a cavity by removing a portion of one of the connection pads and a portion of the insulating resin layer, exposing a sidewall of the electronic component;
depositing a layer of conductive material on the sidewall of the electronic component and on the core of the connection pads; and
separating each of the plurality of chips through the cavity.

2. The method according to claim 1, wherein the core of each connection pad is an electrically conductive core covered by a layer of a solderable material.

3. The method according to claim 2, wherein the solderable material is a tin alloy.

4. The method according to claim 2, wherein the electrically conductive core is copper.

5. The method according to claim 2, wherein the conductive material is a same material as the solderable material.

6. The method according to claim 1, wherein the depositing a layer of conductive material is carried out by screen-printing.

7. An electronic component, comprising:
a chip;
a plurality of connection terminals on the chip;
a plurality of connection pads, each coupled to one of the plurality of connection terminals;
a housing on the chip surrounding the plurality of connection terminals, the housing comprising a first face opposite a second face and a plurality of sidewalls; and
a layer of conductive material covering a portion of the sidewalls and extending over the first face, the layer of conductive material being electrically coupled to the connection terminals of the chip by the connection pads soldered to the connection terminals.

8. The electronic component according to claim 7, wherein the connection pads include an electrically conductive core, at least partially covered by a layer of solderable material coupled to the connection terminals.

9. The electronic component according to claim 7, wherein the layer of conductive material is an alloy of tin.

10. The electronic component according to claim 7, wherein an insulating resin layer covers the first face of the chip between the connection pads.

11. A device, comprising:
a chip with a first face opposite a second face and a plurality of sidewalls extending from the first face to the second face along a first direction;
a plurality of connection terminals on the first face;
an insulating housing covering the first face and having a plurality of sidewalls extending along the first direction;
a plurality of connection pads, each coupled to one of the plurality of connection terminals; and
a first layer of wettable material partially covering a sidewall of the plurality of sidewalls of the insulating housing, the first layer of wettable material being directly coupled to a first one of the plurality of connection pads.

12. The device according to claim 11, wherein the plurality of connection terminals are each separated from a sidewall of the chip by a first distance in the range of 10 μm and 50 μm.

13. The device according to claim 11, wherein the housing entirely covers the first face, the second face, and the plurality of sidewalls of the chip.

14. The device according to claim 11, wherein each connection pad includes an electrically conductive core covered by a layer of a solderable material.

15. The device according to claim 14, wherein the insulating housing has a first face transverse to the plurality of sidewalls of the insulating housing.

16. The device according to claim 15, wherein the layer of wettable material is L-shaped, having a first portion covering a sidewall of the plurality of sidewalls of the insulating housing and a second portion on the first face of the insulating housing.

17. The device according to claim 16, wherein the second portion of the layer of wettable material is coplanar with the first face of the insulating housing.

18. The device according to claim 16, wherein the first and second portions of the layer of wettable material are both coupled directly to the electrically conductive core of the first one of the plurality of connection pads.

19. The device according to claim 16, further comprising a second layer of wettable material directly coupled to a second one of the plurality of connection pads, the second layer of wettable material being coplanar with the first face of the insulating housing.

20. The device according to claim 11, further comprising an insulating resin layer entirely covering the chip.
